(19) United States
(12) Patent Application Publication
(10) Pub. No.: US 2019/0229691 A1
(43) Pub. Date: Jul. 25, 2019

(54) Digital Microphone with a Dynamic Gain Scaling System

(71) Applicant: Robert Bosch GmbH, Stuttgart (DE)

(72) Inventors: Matthew Zeleznik, Pittsburgh, PA (US); Sucheendran Sridharan, McMurray, PA (US)

(21) Appl. No.: 16/319,981

(22) PCT Filed: Aug. 11, 2017
(86) PCT No.: PCT/EP2017/070412

§ 371 Date: Jan. 23, 2019

Related U.S. Application Data
(60) Provisional application No. 62/373,649, filed on Aug. 11, 2016.
(60) Provisional application No. 62/373,673, filed on Aug. 11, 2016.

(51) Int. Cl. H03G 3/30; H03F 3/45; H03M 1/18; H04R 3/00; H04R 1/08

(52) U.S. Cl. CPC H03G 3/3005; H03F 3/45071; H03M 1/183; H04R 3/00; H03F 2200/03; H03F 2200/228; H03F 2203/45528; H03F 2200/129; H03F 2203/45116; H04R 1/08

(57) ABSTRACT

A digital microphone with a dynamic gain scaling system is provided. An ASIC coupled the microphone to the scaling system. An input buffer, a preamplifier, a pair of switching element, a bias source, and a capacitor coupled to the pair of switching element is integrated into the ASIC. In one embodiment, the scaling system is integrated into the ASIC. In another embodiment, the scaling system is a second ASIC and is coupled to the ASIC. The scaling system includes a ADC, a PDM, and a delta-sigma based BR filter and is configured to dynamically adjust various parameters of the ADC, preamplifier, and the bias source.

### FIELD

This disclosure relates generally to digital microphone and, more particularly, to a dynamic gain scaling system for digital microphone.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Embodiments of the disclosure related to a digital microphone with a digital scaling system. An ASIC is coupled to the microphone and the scaling system. A preamplifier, a pair of switching elements, a bias source, and a capacitor coupled to the pair of switching elements is integrated into the ASIC. In one embodiment, the digital scaling system is integrated into the ASIC. In another embodiment, the digital scaling system is a second ASIC and is coupled to the ASIC. The digital gain scaling system is selected from a group consisting of an ADC, a digital attenuator PDM, a bias source, a sensor, an amplifier, and a digital sigma delta based IIR filter to convert a multibit output to a single bit PDB bitstream.

### BRIEF DESCRIPTION OF THE DRAWINGS

These and other features, aspects, and advantages of this disclosure will become better understood when the following detailed description of certain exemplary embodiments is read with reference to the accompanying drawings in which like characters represent like arts throughout the drawings, wherein:

FIG. 1 is a perspective view of a digital microphone in accordance with a described embodiments of a disclosure;

FIG. 2 is a cross-sectional view of the digital microphone of FIG. 1 in accordance with a described embodiment of the disclosure;

FIG. 3 is a schematic block diagram of the digital microphone of FIG. 2 with a dynamic gain scaling system according to an exemplary embodiment of the disclosure;

FIG. 4 is a schematic block diagram of a system having multiple microphones and ASIC coupled to a dynamic gain scaling system according to another embodiment of the disclosure;

FIG. 5 is a schematic circuitry diagram of a portion of the digital microphone of FIG. 5 with a dynamic gain scaling system according to another embodiment of the disclosure;

FIG. 6 is a schematic circuitry diagram of a portion of the digital microphone of FIG. 5 with a dynamic gain scaling system according to another embodiment of the disclosure;

FIG. 7 is a schematic circuitry diagram of a portion of the digital microphone of FIG. 5 with a dynamic gain scaling system according to another embodiment of the disclosure; and

FIG. 8 is a schematic circuitry diagram of a portion of the digital microphone of FIG. 5 with a dynamic gain scaling system according to another embodiment of the disclosure.

### DETAILED DESCRIPTION

The following description is presented to enable any person skilled in the art to make and use the described embodiments, and is provided in the context of a particular application and its requirements. Various modifications to the described embodiments will be readily apparent to those skilled in the art, and the general principles defined herein may be applied to other embodiments and applications without departing from the spirit and scope of the described embodiments. Thus, the described embodiments are not limited to the embodiments shown, but are to be accorded the widest scope consistent with the principles and features disclosed herein.

The disclosure is a microphone system for a client machine. Within the client machine are several other electronic components, such as sensor devices, speakers, graphical processor units, computer processor units, host systems, MEMS microphones, and any suitable computer implemented devices either directly or indirectly coupled to the microphone system. The client machine may be a personal computer or desktop computer, a laptop, a cellular or smart phone, a tablet, a phablet, a personal digital assistant (PDA, Echo, or the like), a gaming console, an audio device, a video device, an entertainment device such as a television, a vehicle infotainment, a wearable device, an entertainment or infotainment remote control, a thin client system, a thick client system, a portable electronic device for playing, streaming, and storing audio, video files, or the like. Other suitable client machines regardless of size, mobility, or configuration may be suggested to include any number of microphone system.

The microphone system includes a package housing or an enclosure for housing any number of sensor devices/dies, internal components, or combination thereof. The sensor devices/dies may be such as MEMS transducers, speakers, receivers, microphones, pressure sensors, thermal sensors, optical sensors, imaging sensors, chemical sensors, gyroscopes, inertial sensors, humidity sensors, accelerometers, gas sensors, environmental sensors, motion sensors, navigation sensors, vital sensors, tunnel magnetoresistive (TMR) sensors, proximity sensors, bolometers, or combination thereof. The microphones may be electret microphones, capacitive microphones, graphene microphones, piezoelectric microphones, silicon microphones, optical microphones, or any suitable acoustic microphones.

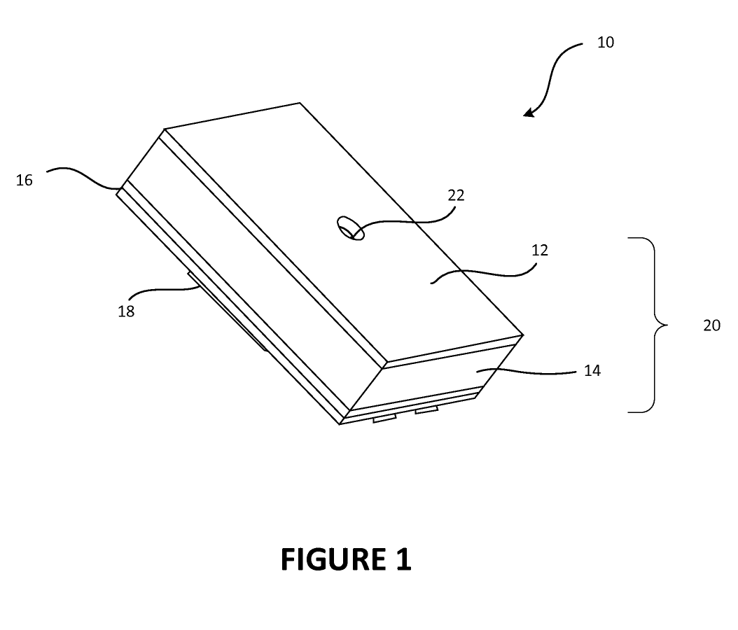

FIG. 1 is a perspective view of a digital microphone 10 according to an embodiment of the disclosure. The digital microphone 10 includes a package housing 20 having a lid 12, a spacer 14, and a substrate 16 attached to the spacer 14 by any suitable methods of attachment. More than one sensor device/die may be mounted within the digital microphone 10. The sensor devices/dies may be MEMS transducers, speakers, receivers, microphones, pressure sensors, thermal sensors, optical sensors, imaging sensors, chemical sensors, gyroscopes, humidity sensors, inertial sensors, vital sensors, TMR sensors, accelerometers, gas sensors, environmental sensors, motion sensors, navigation sensors, proximity sensors, bolometers, or combination thereof. Optional components such as ASICs, integrated circuits, processors, controllers, energy storage devices, actuators, sensor circuits or any suitable circuitry may be mounted within the digital microphone 10. Depending on the application, any number of opening 22 such as a port or a passageway for receiving attributes from an environment may be formed on any location of the package housing 20 by etching, piercing, drilling, punching, or any suitable methods. For example, the opening 22 may be formed on the lid 12, the substrate 16, or the spacer 14. In some embodiments, the opening 22 may be formed on multiple locations of the package housing 20. The attributes may be acoustic signal, pressure signal, optical signal, gas signal, and any suitable signal. Although the digital microphone 10 as depicted comprises a multi-structure package housing 20, various aspects and configurations either in a single structure package housing, a two piece structure package housing, or multi-structure package housing may be used to encapsulate at least one internal component. As an example, the lid 12 and the spacer 14 may be formed as a single structure, defines a cover or a cap. One or more bonding pads 18 may be formed on the substrate 18, the lid 12, the spacer 14, or multiple locations of the package housing 20 by any suitable method. Once bonding pads 18 are introduced, the digital microphone 10 can be easily mounted to an external printed circuit board or another support member of the client machine. In some embodiments, the package housing further includes an interposer coupled the cover 12 to either the spacer 14 or the substrate 16.

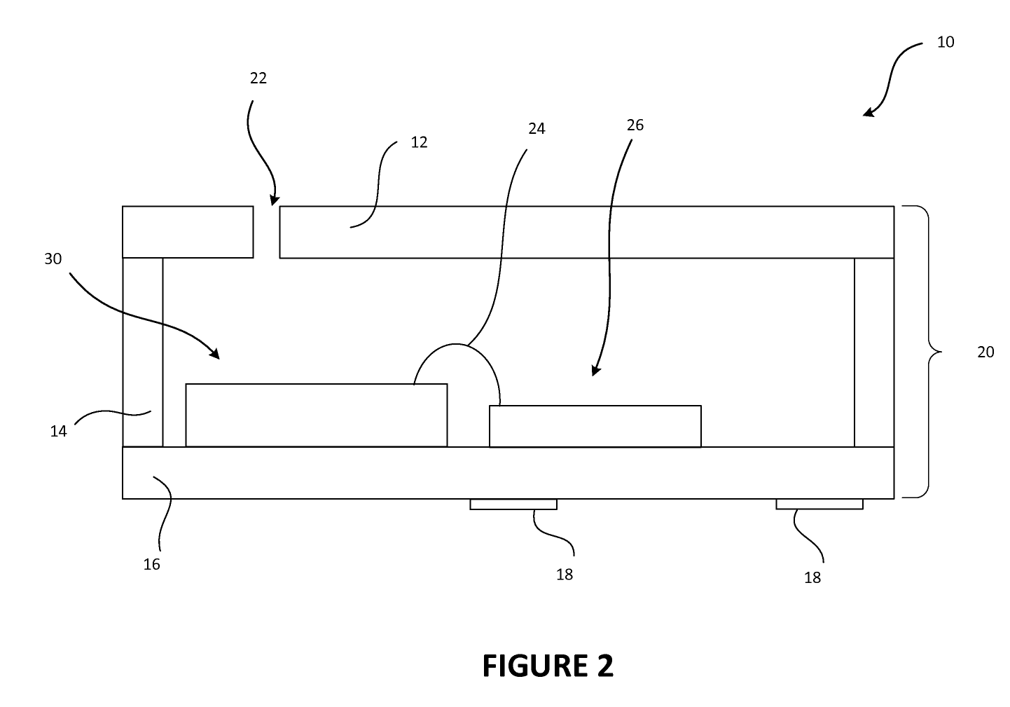

FIG. 2 illustrates a cross-sectional view of the digital microphone 10 of FIG. 1 in accordance with a described embodiment of the disclosure. The digital microphone 10 includes a sensor device/die 30 and a component 26 mounted within any location of the package housing 20. An opening 22 formed on any location of the package housing 20 is adjacent to at least one of the sensor device 30 or the component 26 is provided to receive attributes or stimuli from external environment. A connection link 24 may be introduced to communicatively couple the sensor device 30 to the component 26. The connection link 24 may be wire bonding, solder-bump, solder microbump, solder ball, or any suitable connectors. Depending on the applications, any number of sensor devices 30, components 26, or connection links 24 between the sensor devices and the components may be used. Although side-by-side configuration of the component 26 and the sensor device 30 is illustrated in FIG. 1, any suitable configurations may be possible. For example, the sensor device 30 may be placed or mounted on the component 26 to form a stacked configuration. In another example, the sensor device 30 may be mounted in a hole formed within the component 26 to receive the sensor device to form a surrounded configuration. The sensor device 30 includes a movable member, i.e. diaphragm and a stationary member, i.e. backplate spaced apart from each other.

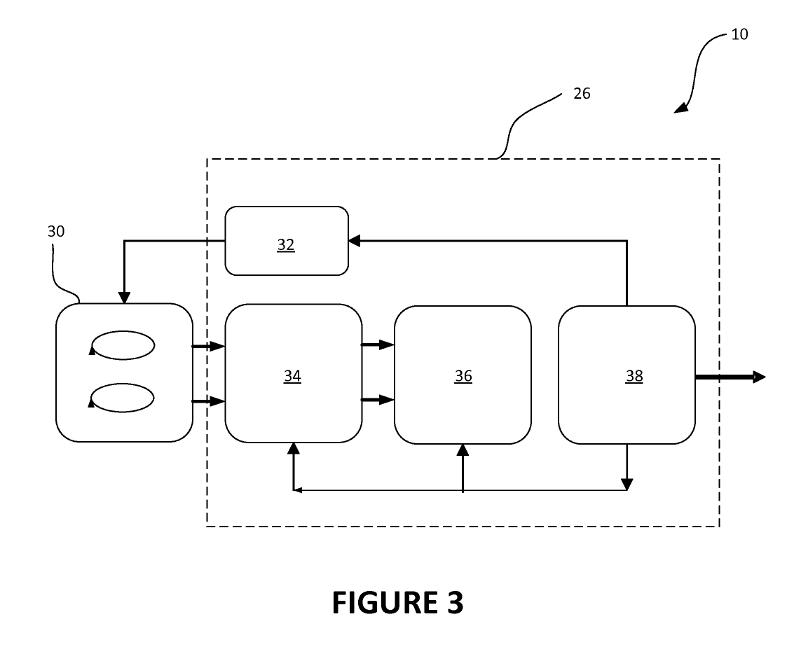

FIG. 3 illustrates a schematic block diagram of the digital microphone 30 of FIG. 2 with a dynamic gain scaling system integrated into a component, such as an application specific integrated circuit (ASIC) 26 according to an exemplary embodiment of the disclosure. Although one microphone 30 is illustrated, two or more microphones coupled to a single or multiple ASIC 26 are possible, depending on the purpose of the application. A membrane of the digital microphone 30 flexes or vibrates up and down in response to a change in air pressure caused by sound waves. The movement of the membrane creates a change in the amount of capacitance between the membrane and a backplate which is translated into an electrical signal as an analog signal for output to the ASIC 26 for processing. The ASIC 26 includes a preamplifier 34, an analog-to-digital converter (ADC) 36 configured to convert analog signals into digital signals and a scaling system 38 coupled to the ADC 36. Other suitable modules, computer implemented modules, volatile modules, or non-volatile modules may be integrated into the ASIC 26. Although the scaling system 38 and the ADC 36 are illustrated as separate modules, depending on the application, the ADC 36 and the scaling system 38 may be integrated into a monolithic module. The monolithic module, depending on the application, may include other modules such as pre-amplifiers, input buffers, and any suitable modules. In some embodiments, the scaling system 38 is an independent module and is communicatively coupled to the ASIC 26. The scaling system 38 is configured to modify various parameters and control various modes performed by other modules 34, 36 and/or the bias voltage source 32.

A pre-amplifier, such as a high impedance pre-amplifier is optionally coupled to a sensor element 30 and is configured to amplify the signals received from the sensor element 30. The ADC 36 receives the analog signals from the pre-amplifier in turn converts the input analog signals into a pulse density modulated (PDM) digital signal for output. The scaling system 38 receives the digital PDM signals and depending on the magnitude of the digital PDM signals either applies, adds, removes, compresses a digital gain, and/or modify at least one of the modules 34, 36, or the bias voltage source 32. In one embodiment, the signal level of the digital microphone 10 can be scaled by adjusting the parameters of the modules 34, 36, or the bias voltage source 32. As one example, the scaling system 38 is configured to adjust or modify the reference voltage in the ADC. As another example, the scaling system 38 is configured to adjust or modify the values of the capacitor in the ADC. As yet another example, the scaling system 38 is configured to adjust or modify the voltage in the bias voltage source.

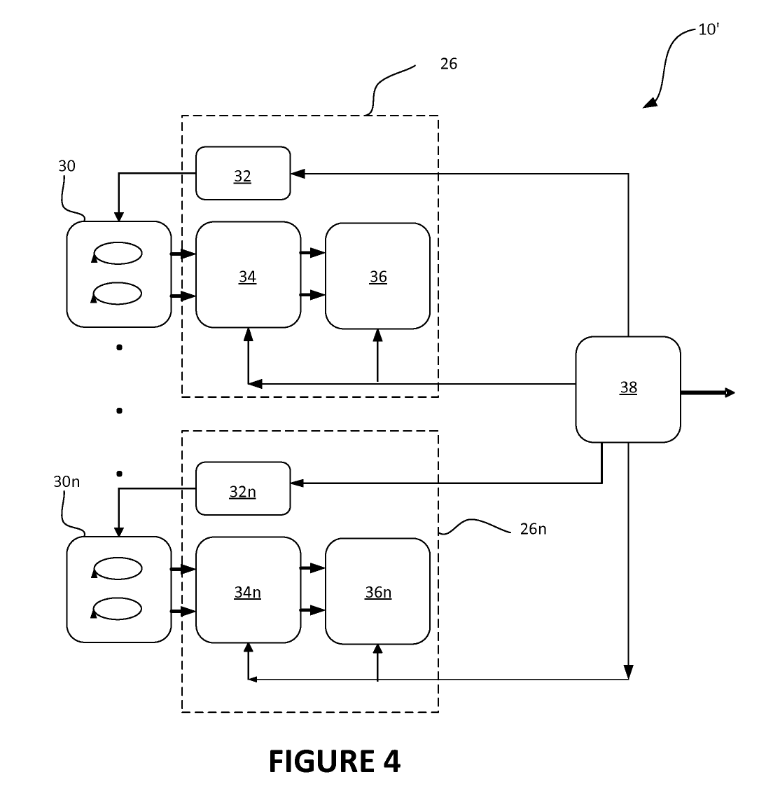

FIG. 4 illustrates a schematic block diagram of a microphone system 10′ according to another embodiment of the disclosure. The microphone system 10′ is similar to the digital microphone 10 of FIG. 3 except that the microphone system 10′ comprises multiple microphones 30, 30n coupled to a three chip system that includes ASIC 26, 26n and a dynamic gain scaling system 38. The scaling system 38 is configured to modify various parameters and control various modes performed by other modules 34, 34n, 36, 36n and/or the bias voltage source 32, 32n. Electrical signals generated by at least one or more of the microphones 30, 30n are output to at least one or more of the ASIC 26, 26n for processing. The signals received by the ASIC 26, 26n are processed before it is output to the scaling system 38 via an input of the scaling system 38. To adjust the parameters of the modules 34, 34n, 36, 36n, and 32, 32n within the ASIC 26, 26n, respectively, the scaling system 38 selectively adjusts or modifies the parameters, such as reference voltage, capacitive values, or biasing values. Although a single scaling system 38 is incorporated to the microphone system 10, more than one scaling system 38 with an optional switching element may be coupled to the ASIC 26, 26n.

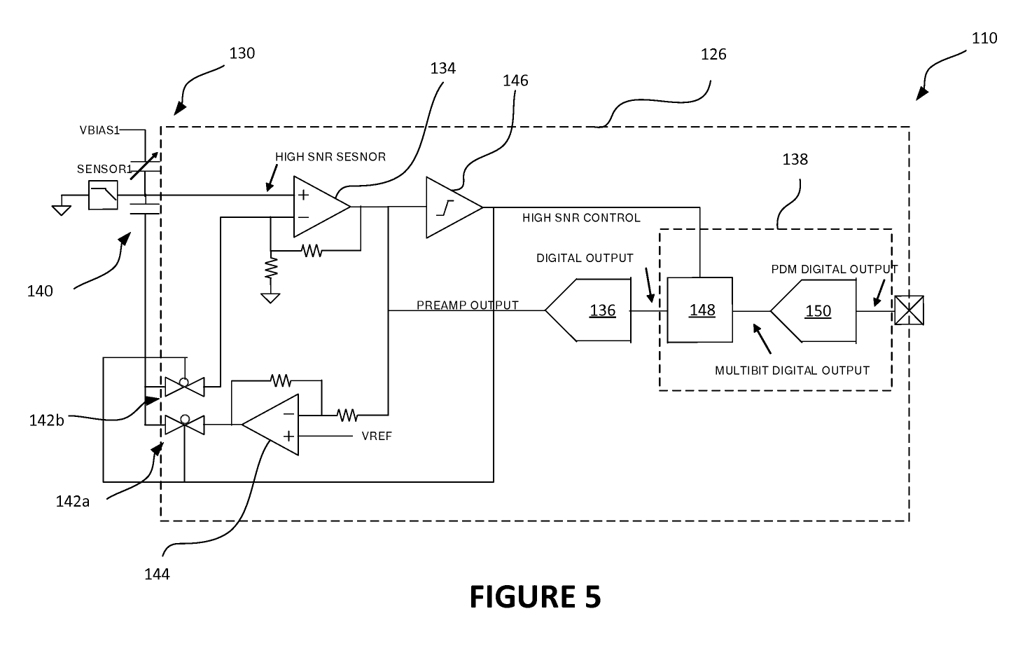

One example of digital microphone 110 with a dynamic gain scaling system according to another embodiment of the disclosure similar to the digital microphone 10 of FIG. 3 is now illustrated in FIG. 5. The digital microphone 110 includes a microphone 130 coupled to an ASIC 126. Electrical signals as analog signals generated by the microphones 130 is output to the ASIC 126 for processing. Within the ASIC 126 includes a preamplifier 134, a threshold detector 146, an ADC 136, a scaling system 138, or any suitable modules 144. Switching elements 142a, 142b coupled to and driven by a capacitor 140 coupled to the microphone 130 may be integrated into the ASIC 126. The signals once amplified by the preamplifier 134 is sent to the threshold detector 146. The threshold detector 146 then detects the signal level of the received signals. If the signal level of the received signals is below a predetermined threshold, the threshold detector 146 then forwards a logic signal to at least one of the switching element 142a and 142b and the signals is fed to the scaling system 138. With a signal below the threshold switch 142b is on and no attenuation is applied to the sensor. The amplified signal is then fed to ADC 136 for converting the amplified signal into digital signal. Concurrently, the scaling system 138 applies an attenuation to the digital data. When the threshold detector 146 receives a signal above a predetermined threshold, switching element 142b is turned on and the input signal is attenuated. At the same time the logic signal is fed to the scaling system 138 and the digital attenuation is turned off. With the digital and analog attenuation levels matched, it is possible to have a linear system that increases in dynamic range by the level of the attenuation applied. The scaling system 138, in one embodiment includes a digital gain scaling block which can be switched to increase the gain of the signal, attenuate the signal or not change the magnitude of the signal.

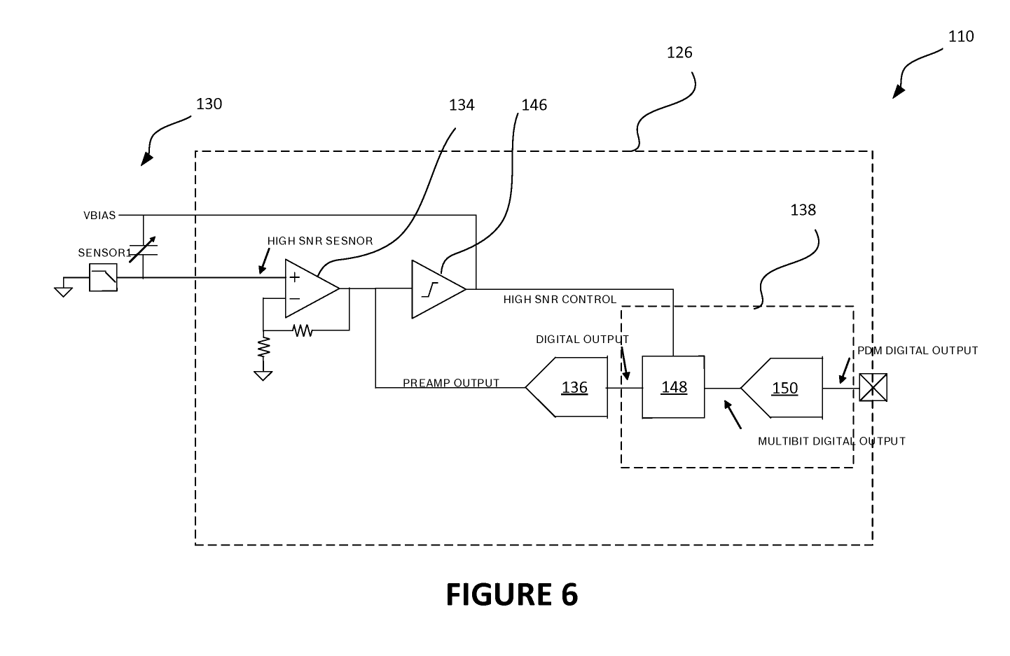

FIG. 6 is a schematic circuitry diagram of a portion of the digital microphone 110 of FIG. 5 with a dynamic gain scaling system 138 according to another embodiment of the disclosure. As previously described, the scaling system 138 is configured to adjust various parameters of the modules within the system 138. In one embodiment, the scaling system 138 receives the attenuated signals from the ADC 136 to adjust the bias voltage in the bias source to accomplish the analog attenuation.

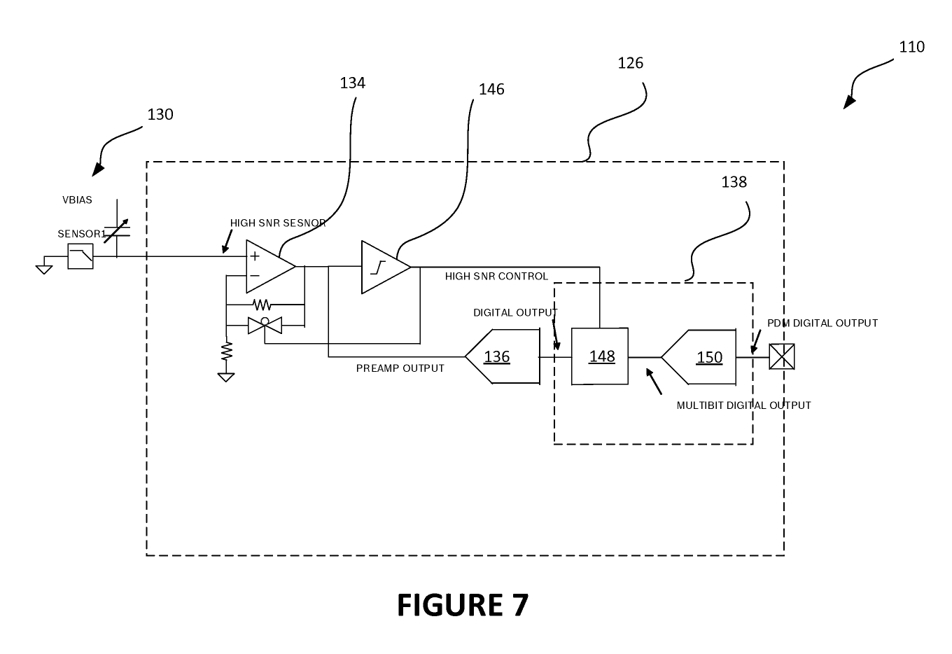

FIG. 7 is a schematic circuitry diagram of a portion of the digital microphone of FIG. 5 with a dynamic gain scaling system according to another embodiment of the disclosure. As previously described, the scaling system 138 is configured to adjust various parameters of the modules within the system 138. In one embodiment, the scaling system 138 receives the attenuated signals from the ADC 136 to adjust preamplifier gain to accomplish the analog attenuation.

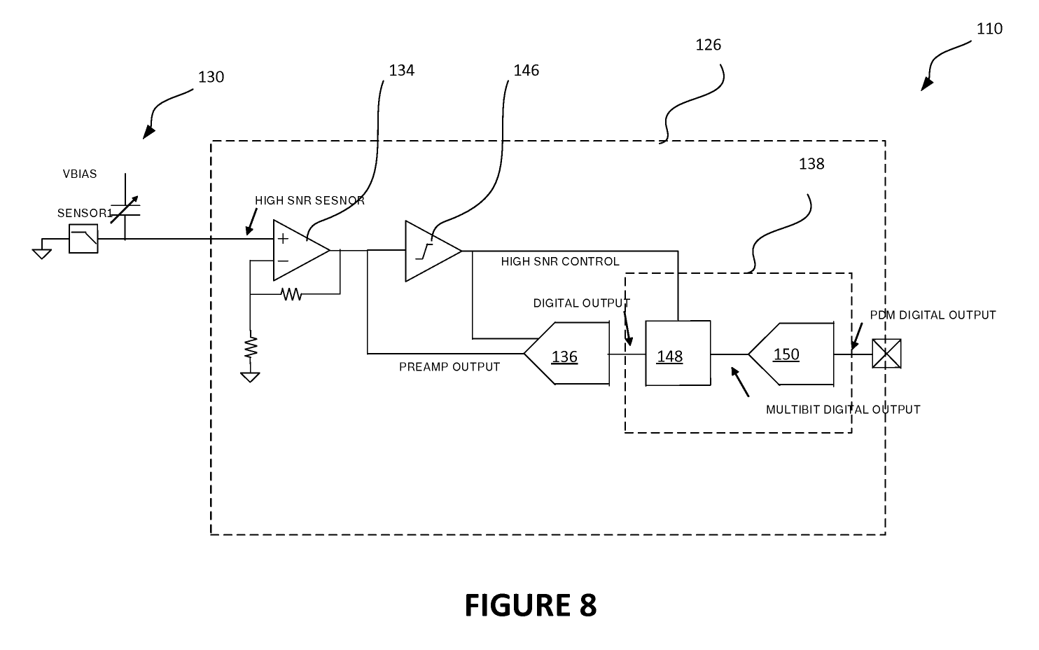

FIG. 8 is a schematic circuitry diagram of a portion of the digital microphone of FIG. 5 with a dynamic gain scaling system according to another embodiment of the disclosure. As previously described, the scaling system 138 is configured to adjust various parameters of the modules within the system 138. In one embodiment, the scaling system 138 receives the attenuated signals from the ADC 136 to adjust the reference voltage in the ADC to accomplish the analog attenuation.

The embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling with the sprit and scope of this disclosure.

While the patent has been described with reference to various embodiments, it will be understood that these embodiments are illustrative and that the scope of the disclosure is not limited to them. Many variations, modifications, additions, and improvements are possible. More generally, embodiments in accordance with the patent have been described in the context or particular embodiments. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. A digital scaling system for a microphone comprising:
a preamplifier coupled to a sensor element, the preamplifier amplifies the signals received from the sensor element;
an analog-to-digital converter (ADC) receives the signals from the preamplifier and converts the signals into a pulse density modulated (PDM) digital signal; and
a scaling device receives the PDM signals from the ADC and modifies at least one of the preamplifier or the ADC.

2. The digital scaling system of claim 1 further comprising a bias voltage source, the scaling device modifies the bias voltage source.

3. The digital scaling system of claim 1 further comprising:
a threshold detector receives the signals from the preamplifier;
a capacitor; and
a switching assembly coupled to and driven by the capacitor, the switching assembly having a first switching element and a second switching.

4. The digital scaling system of claim 3 wherein:
if signal level of the received signal from the preamplifier is below a predetermined threshold, the threshold detector forwards a logic signal to at least one of the first or the second switching element; and
at least one of the first or the second switching element is turned on and no attenuation is applied to the sensor.

5. The digital scaling system of claim 3 wherein:
if signal level of the received signal from the preamplifier is above a predetermined threshold, the threshold detector forwards a logic signal to at least one of the first or the second switching element; and
at least one of the first or the second switching element is turned on and attenuation is applied to the sensor.

6. A microphone package comprising:
a microphone;
a digital scaling system coupled to the microphone, the digital scaling system comprising:
a preamplifier amplifies the signals received from the sensor element;
an analog-to-digital converter (ADC) receives the signals from the preamplifier and converts the signals into a pulse density modulated (PDM) digital signal; and
a scaling device receives the PDM signals from the ADC and modifies at least one of the preamplifier or the ADC.

7. The microphone package of claim 6 wherein the digital scaling system further comprising a bias voltage source, the scaling device modifies the bias voltage source.

8. The microphone package of claim 6 further comprising:
a threshold detector receives the signals from the preamplifier;
a capacitor; and
a switching assembly coupled to and driven by the capacitor, the switching assembly having a first switching element and a second switching.

9. The microphone package of claim 6 wherein:
if signal level of the received signal from the preamplifier is below a predetermined threshold, the threshold detector forwards a logic signal to at least one of the first or the second switching element; and
at least one of the first or the second switching element is turned on and no attenuation is applied to the sensor.

10. The microphone package of claim 8 wherein:
if signal level of the received signal from the preamplifier is above a predetermined threshold, the threshold detector forwards a logic signal to at least one of the first or the second switching element; and
at least one of the first or the second switching element is turned on and attenuation is applied to the sensor.
